(19) United States
(12) Patent Application Publication
(10) Pub. No.: US 2025/0372564 A1
(43) Pub. Date: Dec. 4, 2025

(54) B-STAGE ADHESIVE FOR AN INTERCONNECT

(71) Applicant: TEXAS INSTRUMENTS INCORPORATED, DALLAS, TX (US)

(72) Inventors: JEFF JERARD CANDA, SAN FERNANDO (PH); Lorraine Duldulao Quijano, ANGELES (PH)

(21) Appl. No.: 18/678,537

(22) Filed: May 30, 2024

(51) Int. Cl. H01L 23/00; H01L 21/683; H01L 23/31

(52) U.S. Cl. CPC H01L 24/32; H01L 21/6836; H01L 23/3121; H01L 24/27; H01L 24/29; H01L 24/48; H01L 24/73; H01L 2224/27472; H01L 2224/27515; H01L 2224/2919; H01L 2224/32014; H01L 2224/32245; H01L 2224/48247; H01L 2224/73265; H01L 2924/3512

(57) ABSTRACT

A method for forming an integrated circuit (IC) is provided. In one example, the method includes applying a stencil to an interconnect. The stencil includes a number of openings corresponding to interconnect locations. The method also includes applying an adhesive to the interconnect through the number of openings to form an adhesive layer at an interconnect location of the interconnect locations. The method further includes performing a first cure of the adhesive layer. The method yet further includes attaching a die to the interconnect at the at least one interconnect location. The adhesive layer electrically insulates the die from the interconnect. The method includes performing a second cure of the adhesive layer.

### TECHNICAL FIELD

This description relates to depositing B-stage adhesive on the interconnect using a stencil.

### BACKGROUND

A vast array of electronic devices, such as cellular phones, digital cameras, and music players, are packing more integrated circuits into an ever-shrinking physical space with expectations for decreasing cost. Integrated circuits used in the variety of electronic devices are typically manufactured on a wafer. For example, dies of the wafer are affixed to a die attach pad or wire bond pad(s) of an interconnect. However, the wafer is at risk of cracking and/or breakage during processing and packaging. For example, the current manufacturing techniques increase risk by screen printing an adhesive on the wafer. Cracking and/or breakage of the wafer contribute to waste and increased manufacturing cost.

### SUMMARY

In one example, a method of forming an integrated circuit (IC) is provided. The method includes applying a stencil to an interconnect. The stencil includes a number of openings corresponding to interconnect locations. The method also includes applying an adhesive to the interconnect through the number of openings to form an adhesive layer at an interconnect location of the interconnect locations. The method further includes performing a first cure of the adhesive layer. The method yet further includes attaching a die to the interconnect at the interconnect location. The adhesive layer electrically insulates the die from the interconnect. The method includes performing a second cure of the adhesive layer.

Another example relates to another method of forming an IC. The method includes applying an adhesive to an interconnect to form an adhesive layer at a die attach pad. The method also includes performing a first cure of the adhesive layer. The method further includes attaching a die to the interconnect at a die attach pad. The adhesive layer electrically insulates the die from the interconnect. The method yet further includes performing a second cure of the adhesive layer.

In yet another example, a semiconductor device is provided. The semiconductor device includes a plurality of wire bond pads having an adhesive layer applied to a region of surfaces of the plurality of wire bond pads. The adhesive layer has a first adhesive dimension extending in a first direction and a second adhesive dimension extending in a second direction orthogonal to the first direction. The semiconductor device also includes a die having a base surface affixed to the plurality of wire bond pads by the adhesive layer. The base surface has a first die dimension and a second die dimension orthogonal to the first die dimension. The first adhesive dimension and the second adhesive dimension are based on a first wire bond pad dimension and a second wire bond pad dimension of a wire bond pad of the wire bond pads.

### BRIEF DESCRIPTION OF THE DRAWINGS

FIG. 1 illustrates an example of a semiconductor ready for packaging with an adhesive layer.

FIG. 2 illustrates an example of an interconnect.

FIG. 3 illustrates an example of a stencil for applying the adhesive layer to the interconnect.

FIG. 4 illustrates another example of a stencil for applying the adhesive layer to the interconnect.

FIG. 5 illustrates a chip on lead configuration of a semiconductor ready for packaging with an adhesive layer.

FIG. 6 illustrates an example of a first stage of the method for forming a semiconductor ready for packaging with an adhesive layer.

FIG. 7 illustrates an example of a second stage of the method for forming the semiconductor ready for packaging with an adhesive layer.

FIG. 8 illustrates an example of a third stage of the method for forming the semiconductor ready for packaging with an adhesive layer.

FIG. 9 illustrates an example of a fourth stage of the method for forming the semiconductor ready for packaging with an adhesive layer.

FIG. 10 illustrates an example of a fifth stage of the method for forming the semiconductor ready for packaging with an adhesive layer.

FIG. 11 illustrates an example of a sixth stage of the method for forming the semiconductor ready for packaging with an adhesive layer.

FIG. 12 illustrates an example of a seventh stage of the method for forming the semiconductor ready for packaging with an adhesive layer.

FIG. 13 illustrates an example of an eighth stage of the method for forming the semiconductor ready for packaging with an adhesive layer.

FIG. 14 illustrates an example of a ninth stage of the method for forming the semiconductor ready for packaging with an adhesive layer.

FIG. 15 illustrates an example of a tenth stage of the method for forming the semiconductor ready for packaging with an adhesive layer.

FIG. 16 illustrates an example of an eleventh stage of the method for forming the semiconductor ready for packaging with an adhesive layer.

FIG. 17 illustrates an example of a twelfth stage of the method for forming the semiconductor ready for packaging with an adhesive layer.

FIG. 18 illustrates an example of a thirteenth stage of the method for forming the semiconductor ready for packaging with an adhesive layer.

FIG. 19 illustrates an example of a fourteenth stage of the method for forming the semiconductor ready for packaging with an adhesive layer.

FIG. 20 illustrates an example of a fifteenth stage of the method for forming the semiconductor ready for packaging with an adhesive layer.

FIG. 21 illustrates a flowchart of an example method for fabricating a wafer semiconductor with an adhesive layer.

### DETAILED DESCRIPTION

Conventionally, a semiconductor die is affixed to an interconnect with an adhesive layer. In particular, the adhesive layer, such as B-stage epoxy, is screen printed on the wafer. The screen-printing process on the wafer has a high risk of wafer cracking and/or breakage. Furthermore, this process complicates manufacturing by adding additional steps for the application of the adhesive to the wafer prior to singulation.

To reduce cost and complexity, the devices and methods herein apply the adhesive layer to the interconnect rather than the wafer. For example, during manufacturing, an adhesive is applied to the interconnect to form an adhesive layer. In one example, the adhesive layer is formed by applying adhesive to the interconnect through openings in a stencil. The dimensions of the openings in the stencil define the dimensions of the adhesive layer. In response to the adhesive layer being deposited on the interconnect, the adhesive layer undergoes a first cure, the semiconductor die is affixed to a portion of the interconnect via the adhesive layer, and a second cure is performed. Forming the adhesive layer on the interconnect reduces the potential of mishandling the wafer, thereby reducing cracking and/or breakage of the wafer and simplifying the manufacturing process.

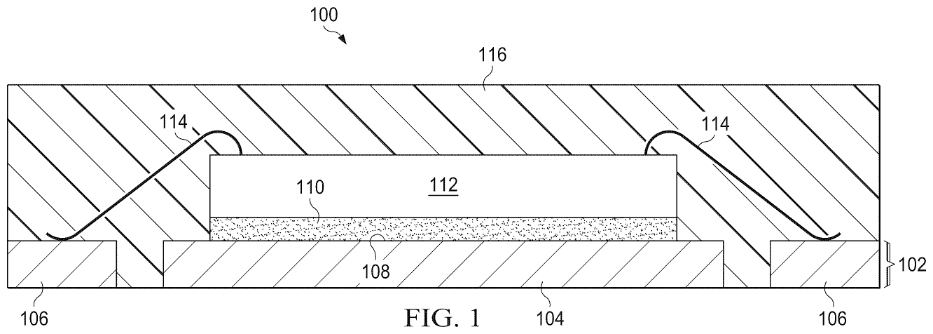

FIG. 1 illustrates an example of a semiconductor ready for packaging with an adhesive layer. The semiconductor device 100 includes an interconnect 102 forming a die attach pad 104 and a number of wire bond pad(s) 106. The interconnect 102 is formed of an electrically conductive material, such as copper, palladium, gold, silver, or other appropriate conductive metal or metal alloy with similar properties. For example, the interconnect 102 is formed from a copper sheet. An adhesive is applied to a surface portion 108 of the interconnect 102 to form an adhesive layer 110. For example, the surface portion 108 of the interconnect 102 is a top surface of the die attach pad 104. The adhesive layer may be continuous, as shown here, or discontinuous.

The adhesive layer 110 bonds a die 112 to the die attach pad 104. The adhesive layer 110 is formed of an adhesive that is a low reactivity curing agent. In one example, the adhesive is a thermosetting resin with high cohesive strength. As one example, the adhesive is a B-stage epoxy resin. A bond wire 114 is attached at the die 112 and the wire bond pad(s) 106 to form an electrical connection between the die 112 and the wire bond pad(s) 106. The die attach pad 104, wire bond pad(s) 106, adhesive layer 110, the die 112, and the bond wire(s) 114 are at least partially encapsulated in a molding compound 116 to form a packaged semiconductor device 100, such as an integrated circuit (IC) or a system on chip (SOC). The molding compound 116 is formed of one or more insulating materials, such as organic resins (e.g., epoxy), inorganic resins, and/or other suitable materials.

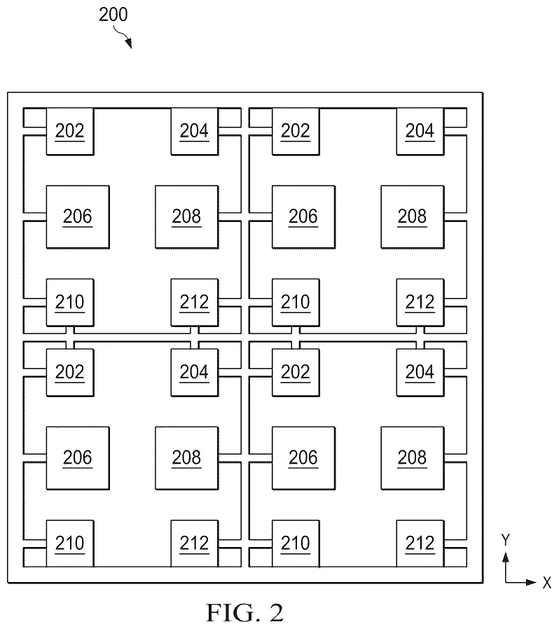

FIG. 2 illustrates an example of an interconnect 200 (e.g., the interconnect 102 of FIG. 1). The interconnect 200 is formed of an electrically conductive material, such as copper, palladium, gold, silver, or other appropriate conductive metal or metal alloy with similar properties. The interconnect 200 includes saw streets, tie bars, and a number of interconnect locations including a first interconnect location 202, a second interconnect location 204, a third interconnect location 206, a fourth interconnect location 208, a fifth interconnect location 210, and a sixth interconnect location 212. The interconnect locations 202-212 are regions of the interconnect 200 that may be affixed to a die (e.g., the die 112 of FIG. 1) and include die attach pad(s) (e.g., the die attach pad 104 of FIG. 1) and wire bond pad(s) (e.g., the wire bond pad 106 of FIG. 1). For example, for a chip on lead device, the interconnect locations 202-212 correspond to wire bond pad(s).

An interconnect location of the interconnect locations 202-212 have interconnect dimensions including a first interconnect dimension and a second interconnect dimension. For example, the first interconnect location 202 has a first interconnect dimension extending in the x-direction and a second interconnect dimension extending in the y-direction approximately orthogonal to the x-direction. The x-direction and the y-direction forming an x-y plane. In some examples, the interconnect dimensions are dependent on a type of interconnect location, the die dimensions of the die, etc. Suppose the first interconnect location 202 is a wire bond pad. The first interconnect dimension is a first wire bond pad dimension, and the second interconnect dimension is a second wire bond pad dimension. Adhesive is applied to a surface portion (e.g., the surface portion 108 of FIG. 1) of the interconnect 200 defined in the x-y plane. To control the application of adhesive to the interconnect locations 202-212, a stencil may be placed on the surface portion of the interconnect 200.

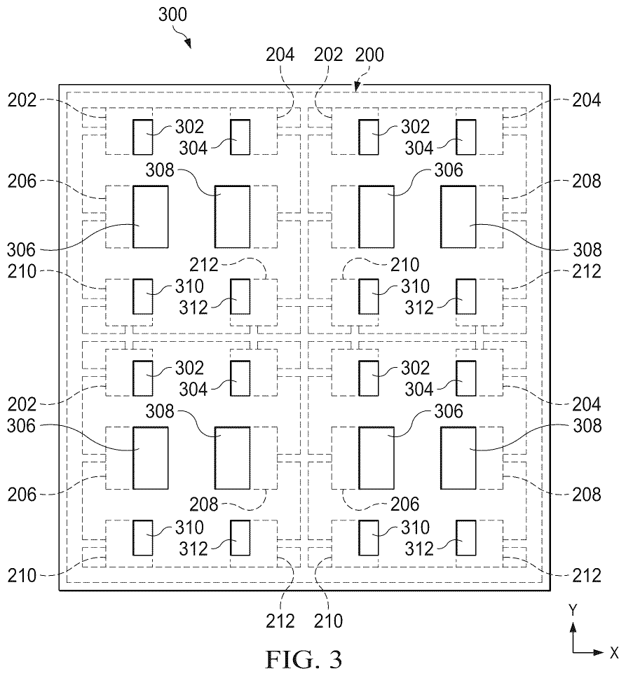

FIG. 3 illustrates an example of a stencil 300 for applying adhesive to the interconnect 200 as shown in FIG. 2. For purposes of simplification, FIGS. 2 and 3 employ the same reference numbers to denote the same structure. The interconnect 200 is illustrated in dashed lines to demonstrate that the interconnect 200 is underneath the stencil 300.

The stencil 300 is a frame having a number of openings corresponding to interconnect locations 202-212. The stencil 300 is formed of metal, metal alloy, polymer (e.g., rubber, plastic, resins, etc.), or other material to prevent the flow of adhesive to the interconnect 200 through the frame. The number of openings allow adhesive to flow to the interconnect 200 at predetermined locations. For example, the openings include a first opening 302, a second opening 304, a third opening 306, a fourth opening 308, a fifth opening 310, and a sixth opening 312. The first opening 302 exposes the first interconnect location 202, the second opening 304 exposes the second interconnect location 204, and so on. The openings 302-312 have a first adhesive dimension extending in a first direction and a second adhesive dimension extending in a second direction approximately orthogonal to the first direction. For example, the first opening 302 has a first adhesive dimension extending in the x-direction and a second adhesive dimension in the y-direction.

During application of adhesive, the adhesive is applied to the stencil 300 and through the opening 302-312 to the surface portion of the interconnect locations 202-212 exposed by the openings 302-312. The first adhesive dimension corresponds to the first interconnect dimension. For example, like the first interconnect dimension, the first adhesive direction extends in the x-direction. The second adhesive dimension corresponds to the second interconnect dimension, for example, extending in the y-direction approximately orthogonal to the x-direction. The first adhesive dimension is less than or equal to the first interconnect dimension. The second adhesive dimension is less than or equal to the second interconnect dimension. Accordingly, the flow of the adhesive is limited to portions of the interconnect locations 202-212 exposed by the corresponding openings 302-312 to form an adhesive layer (e.g., the adhesive layer 110 of FIG. 1).

The adhesive is applied by a screen-printing process, dispensing process, or jetting process, among others. In some examples, the adhesive is spread over the stencil and through the openings 302-312 with a flat, smooth blade (i.e., squeegee, squilgee, etc.), used to remove or control the flow of liquid on a flat surface. The adhesive forms the adhesive layer of adhesive sections on the interconnect locations 202-212 corresponding to the openings 302-312. Remaining portions of the interconnect locations 202-212 that are covered by the stencil 300 do not receive adhesive. For example, the first interconnect location 202 includes an adhesive section and a remaining portion. The adhesive section has a size corresponding to the adhesive dimensions of the first opening 302. The remaining portion of the first interconnect location 202 is the area of the surface portion of the first interconnect location 202 covered by the stencil 300.

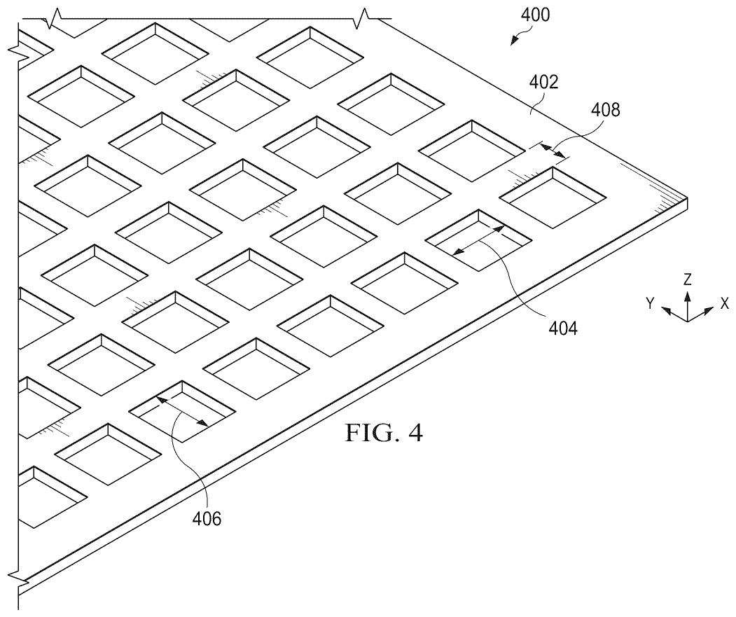

FIG. 4 illustrates another example of a stencil 400 (e.g., the stencil 300 of FIG. 3) for applying the adhesive layer (e.g., the adhesive layer 110 of FIG. 1) to the interconnect (e.g., the interconnect 102 of FIG. 1, the interconnect 200 of FIGS. 2, 3). The stencil 400 has a number of openings (e.g., the openings 302-312 of FIG. 3) including a respective opening 402. The respective opening 402 has a first adhesive dimension 404 extending in a first direction, a second adhesive dimension 406 extending in a second direction, and a third adhesive dimension 408 extending in a third direction. In one example, the first direction is the x-direction, and the second direction is the y-direction orthogonal to the x-direction. The third direction is the z-direction, approximately orthogonal to the x-y plane. The third adhesive dimension 408 defines an adhesive thickness of an adhesive layer (e.g., the adhesive layer 110 of FIG. 1). The third adhesive dimension 408 corresponds to the stencil thickness of the stencil 400.

In some examples, the first adhesive dimension 404, the second adhesive dimension 406, and/or the third adhesive dimension 408 are based on a tolerance threshold. The tolerance threshold corresponds to an expected amount of bleed out of the adhesive from under a die (e.g., the die 112 of FIG. 1) applied to the adhesive layer. Accordingly, the adhesive dimensions 404-408 may be smaller than the region of the interconnect locations (e.g., the interconnect locations 202-212 of FIG. 2) that are overlaid by the die to accommodate the bleed out. In one example, one or more of the adhesive dimensions 404-408 are smaller than the region of the interconnect location to be overlaid by the die by the distance of the tolerance threshold. In some instances, the length of the tolerance threshold may be further based on a type of the adhesive, the viscosity of the adhesive, and/or a cure schedule of the adhesive.

The stencil 400 allows the volume and placement of the adhesive layer to be controlled. For example, controlling the first adhesive dimension 404, the second adhesive dimension 406, and the third adhesive dimension 408 of the respective opening 402 regulates the volume and dimensions of the resulting adhesive layer. Likewise, the location of the respective opening 402 of the stencil 400 relative to the interconnect determines the location of the resulting adhesive layer. By controlling the volume and placement of the adhesive layer, the application of the adhesive can be tailored to different configurations of semiconductor devices.

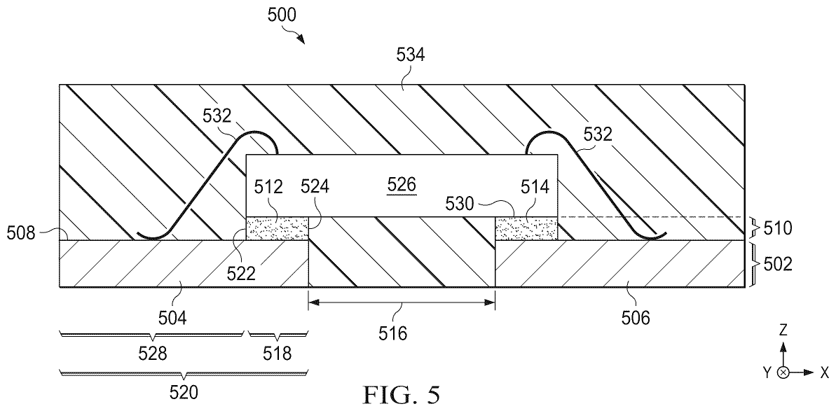

FIG. 5 illustrates a chip on lead (COL) configuration of a semiconductor ready for packaging with an adhesive layer. The semiconductor device 500 includes an interconnect 502 (e.g., the interconnect 102 of FIG. 1, the interconnect 200 of FIG. 2) having a number of interconnect locations (e.g., the interconnect locations 202-212 of FIG. 2). The interconnect locations include a first wire bond pad 504 and a second wire bond pad 506 (e.g., the wire bond pad 106 of FIG. 1).

An adhesive is applied to a surface portion 508 of the interconnect 502 to form an adhesive layer 510 (e.g., the adhesive layer 110 of FIG. 1). The adhesive layer 510 is discontinuous and includes a first adhesive section 512 and a second adhesive section 514 are coplanar and separated by a gap distance 516 in a first direction. The gap distance 516 may be the distance between the first wire bond pad 504 and the second wire bond pad 506. For example, the gap distance is the distance between an edge of the first wire bond pad 504 and the second wire bond pad 506 in the first direction.

The first adhesive section 512 has a first adhesive dimension 518 extending in a first direction, in one example, the x-direction. The first adhesive dimension is less than the first interconnect dimension 520 of the first wire bond pad 504. In one example, the first adhesive dimension 518 extends from a first edge 522 opposite a second edge 524 in the first direction. The first edge 522 is approximately collinear with an edge of a die 526 overlaying the adhesive layer 510. The second edge 524 is approximately collinear with an edge of the first wire bond pad 504. The remaining portion of the first interconnect dimension 520 of the first wire bond pad 504 has a first remainder dimension 528 that corresponds to the length, in the first direction of the surface portion 508 that is not overlayed by the first adhesive section 512.

The adhesive layer 510 bonds the die 526 to a top surface 530 of the interconnect 502. The adhesive layer 510 is, for example, a filmy adhesive agent, such as a B-stage epoxy resin. A bond wire 532 (e.g., the bond wire 114 of FIG. 1) forms an electrical connection between the interconnect 502 and the die 526. For example, the bond wire 532 is attached at the die 526 and the second wire bond pad 506 and forms an electrical connection between the die 526 and the wire bond pad 506. The wire bond pads 504, 506, adhesive layer 510, the die 526, and the bond wire(s) 532 are at least partially encapsulated in a molding compound 534 (e.g., the molding compound 116 of FIG. 1) to form a packaged semiconductor device 500, such as a COL semiconductor device.

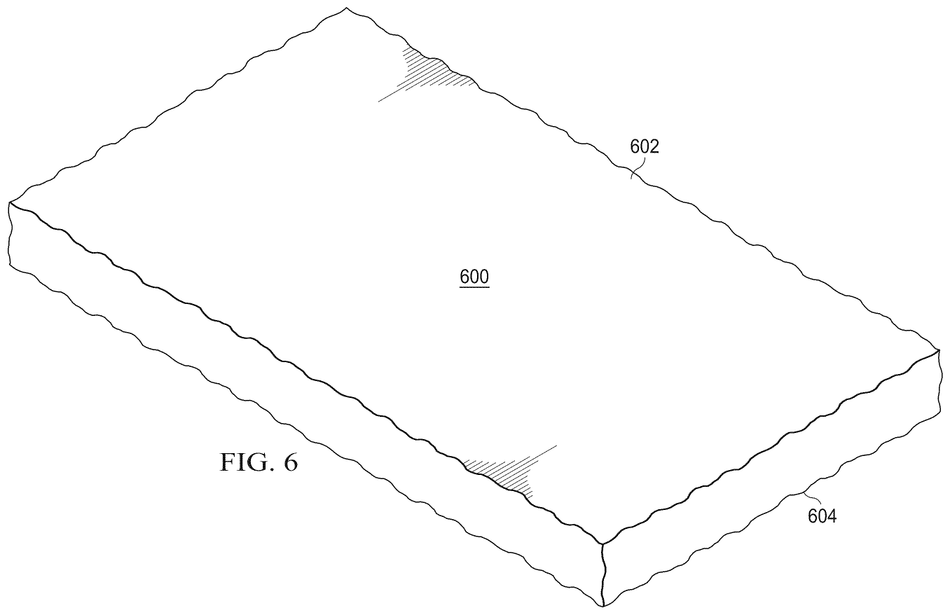

FIGS. 6-20 illustrate stages of a method for formation of a semiconductor ready for packaging, such as semiconductor device 500 of FIG. 5 with an adhesive layer. For purposes of simplification, FIGS. 6-20 employ the same reference numbers to denote the same structure.

FIG. 6 illustrates an example of a first stage of a method of forming the semiconductor ready for packaging with an adhesive layer. For example, FIG. 6 illustrates an example of a semiconductor wafer 600 having a first surface 602 opposite a second surface 604. The semiconductor wafer 600 is a substrate, such as silicon, silicon carbide, or other suitable material, either in substantially pure form or in combination with additional materials. As another example, the semiconductor wafer 600 is a single crystal material, such as a single crystal silicon substrate. As yet another example, the semiconductor wafer 600 is a complementary metal-oxide semiconductor (CMOS) substrate and includes circuitry formed thereon. The formation of the semiconductor wafer 600 is dependent on the application of the semiconductor device (e.g., the semiconductor device 100 of FIG. 1, the semiconductor device 500 of FIG. 5) being fabricated.

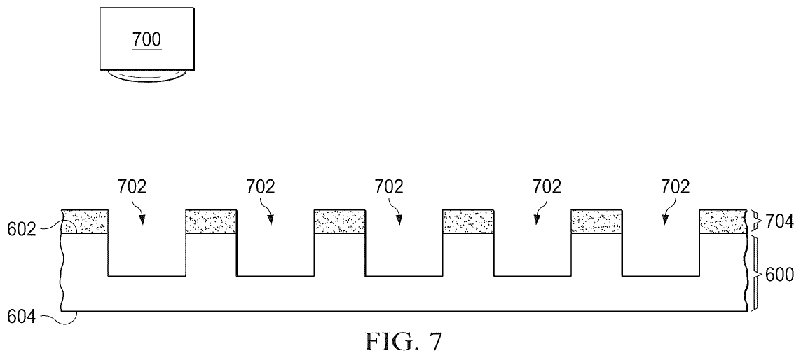

FIG. 7 illustrates an example of a second stage of the method for forming the semiconductor ready for packaging with an adhesive layer. In the second stage, a feature tool 700 removes wafer material from the first surface 602 of the semiconductor wafer 600 to form the voids 702. For example, the feature tool 700 is an etch apparatus laser, saw, etc. The voids 702 can have a variety of shapes. In some examples, the voids 702 have spaced apart sidewalls that extend toward the second surface 604 approximately orthogonally to the first surface 602 to form spaced apart die sidewalls.

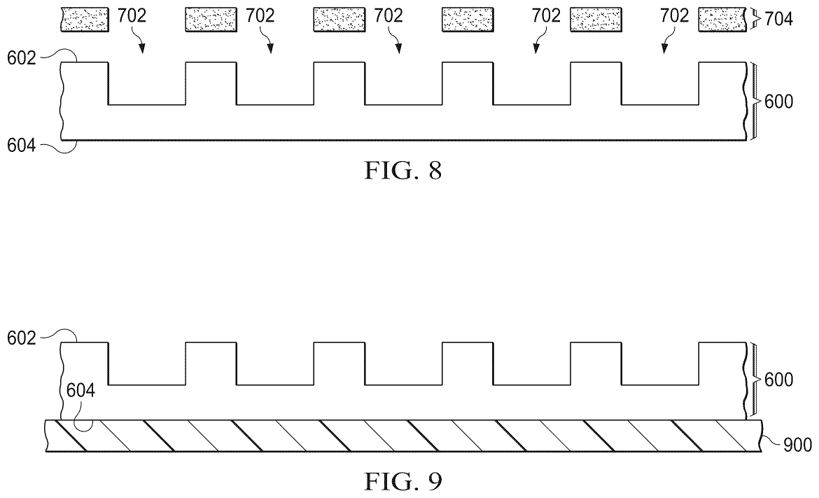

In some examples, a photoresist layer 704 is formed on the first surface 602 of the semiconductor wafer 600 and patterned by a performing selective irradiation. The irradiated or nonirradiated portions are removed by applying a developer material. For example, a dry plasma etch is performed on the first surface 602 to form the voids 702. The dry plasma etch is based on the type of material forming the semiconductor wafer 600. For example, the plasma etch is a chlorine-based plasma etch and the feature tool is a parallel plate Reactive Ion Etch apparatus, Inductively Coupled Plasma reactor or, alternatively, an electron cyclotron resonance plasma reactor. In response to the voids 702 being formed, the photoresist layer 704 is removed from the first surface 602 of the semiconductor wafer 600, as shown in a third stage illustrated in the example of FIG. 8.

In some examples, the initial wafer thickness of the semiconductor wafer 600, defined by the distance between the first surface 602 and the second surface 604, is adjusted by back grinding. In a fourth stage, as shown in the example of FIG. 9, a back grinding tape 900 is applied to the second surface 604 of the semiconductor wafer 600. The back grinding tape 900 supports the semiconductor wafer 600 during back grinding. Additionally, the back grinding tape 900 can act as a layer for protecting the second surface 604 of the semiconductor wafer 600 during back grinding.

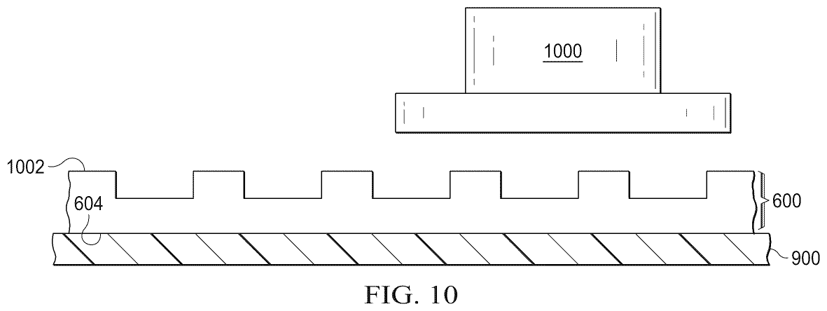

In the fifth stage, illustrated in the example of FIG. 10, the first surface 602 of the semiconductor wafer 600 is grinded with a grinding tool 1000 to remove material from the first surface 602 forming an adjusted first surface 1002. An adjusted wafer thickness is defined as the distance between the adjusted first surface 1002 and the second surface 604. The adjusted wafer thickness is less thick than the initial wafer thickness since wafer material is removed. In some examples, the semiconductor wafer 600 is positioned upside down for back grinding.

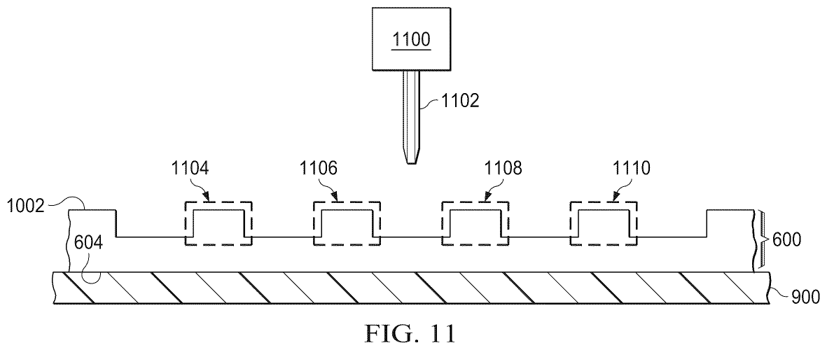

In a sixth stage, shown in the example of FIG. 11 individual dies are singulated from the semiconductor wafer 600. The singulation process utilizes a severing tool 1100. For example, the severing tool 1100 is a saw that includes a saw blade 1102 that scribes, saws or dices through a height of the semiconductor wafer 600 in the lateral direction in a seventh stage. The saw blade 1102 travels a path from the second surface 604 to the first surface 602 through the semiconductor wafer 600. In other examples, the severing tool 1100 is laser-based or plasma-based.

In some instances, a dicing tape is applied. For example, the back grinding tape 900 is removed from the adjusted first surface 1002, and a dicing tape, such as an ultraviolet (UV) tape, is applied to the adjusted first surface 1002 of the semiconductor wafer 600. In some examples, the semiconductor wafer 600 with the dicing tape is positioned on a carrier, frame, or other suitable surface to support the semiconductor wafer 600 during a singulation process. A first die 1104, a second die 1106, a third die 1108, and a fourth die 1110 result from the singulation process.

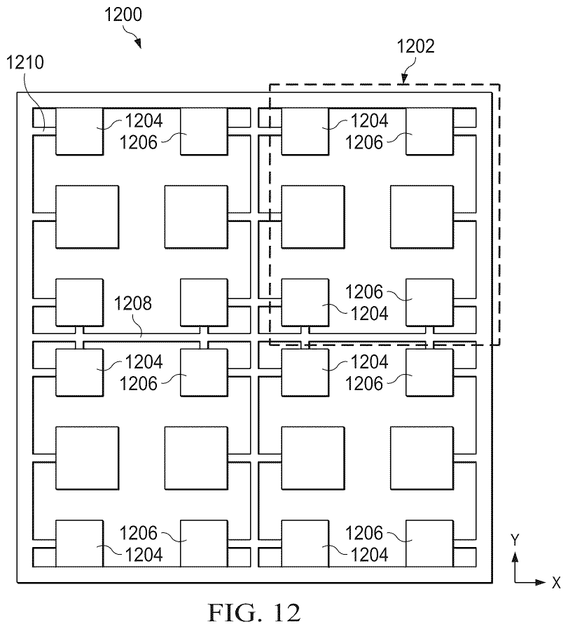

FIG. 12 illustrates an example of a seventh stage of the method for forming the semiconductor ready for packaging with an adhesive layer. In the seventh stage, an interconnect 1200 (e.g., the interconnect 102 of FIG. 1, the interconnect 200 of FIG. 2) is provided. As one example, the interconnect 1200 accommodates four dies (e.g., a first die 1104, a second die 1106, a third die 1108, and a fourth die 1110 of FIG. 11). For example, an interconnect area 1202 is configured to accommodate a single die.

For a chip on lead configuration of a semiconductor, such as the semiconductor device 500 shown in FIG. 5, the interconnect area 1202 has wire bond pads (e.g., the wire bond pad(s) 106 of FIG. 1) including a first wire bond pad 1204 and a second wire bond pad 1206 that are electrically isolated from each other. For other configurations of a semiconductor device, such as the semiconductor device 100 of FIG. 1, the interconnect may include a die attach pad (e.g., the die attach pad 104 of FIG. 1) and wire bond pads. The wire bond pads 1204, 1206 are typically connected to saw streets 1208 with tie bars 1210. The saw streets 1208 and the tie bars 1210 are formed of thin metal strips. The saw streets 1208 support the interconnect 1200 during die attach (IC chip attachment to the interconnect), wire bonding (wire connecting IC bond pads to wire bond pads), and potting (encapsulation of the IC chip, wire bonds, and interconnects 1200 with molding compound). Sawing along the saw streets 1208 separates the individual packaged IC chips including a die on an interconnect area 1202.

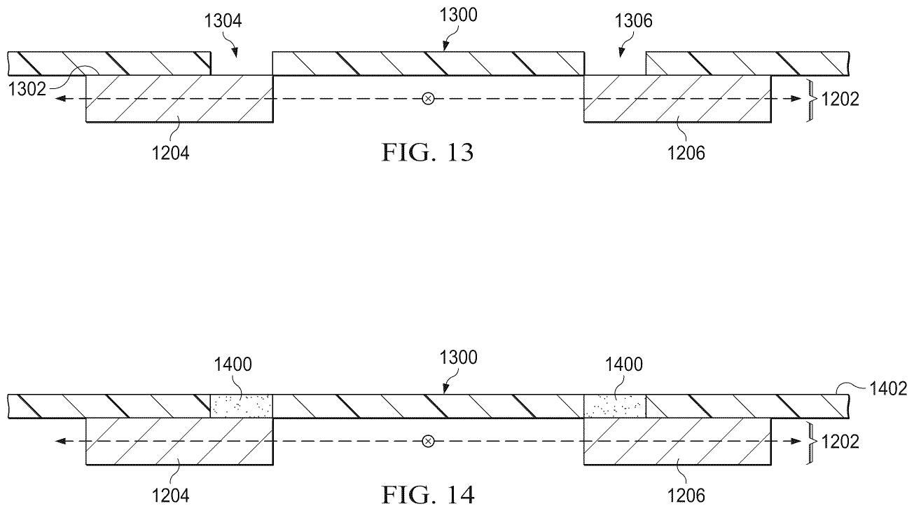

FIG. 13 illustrates an example of an eighth stage of the method for forming the semiconductor ready for packaging with an adhesive layer. For clarity, the remaining stages will be shown and described with respect to a portion of the interconnect area 1202. In the eighth stage, a stencil 1300 (e.g., the stencil 300 of FIG. 3, the stencil 400 of FIG. 4) is placed on a first surface 1302 of the interconnect 1200. The stencil 1300 may rest on the first surface 1302 or be affixed to the first surface 1302. The placement of the stencil 1300 aligns a number of openings (e.g., the openings 302-312 of FIG. 3) including a first opening 1304 and a second opening 1306 over at least a portion of the interconnect location(s) such as the first wire bond pad 1204 and the second wire bond pad 1206. In another example, the number of openings 1304, 1306 correspond to a die attach pad (e.g., the die attach pad 104 of FIG. 1) on the interconnect 1200.

FIG. 14 illustrates an example of a ninth stage of the method for forming the semiconductor ready for packaging with an adhesive layer. In the ninth stage, an adhesive 1400 is applied to the interconnect 1200 through the first opening 1304 and the second opening 1306 and onto a surface 1402 of the stencil 1300. The adhesive 1400 is applied in a printing process, dispensing process, or jetting process, among others. In some examples, the adhesive 1400 is spread over the surface 1402 of the stencil 1300 and through the first opening 1304 and the second opening 1306. Any remaining adhesive 1400 on the surface 1402 of the stencil 1300 with a flat, smooth blade (i.e., squeegee, squilgee, etc.).

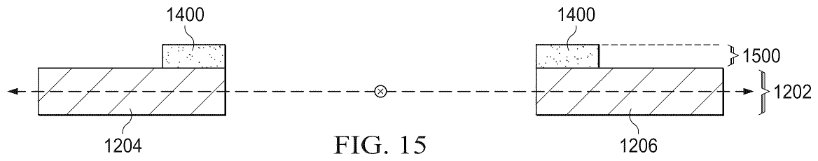

FIG. 15 illustrates an example of a tenth stage of the method for forming the semiconductor ready for packaging with an adhesive layer. In the tenth stage, the stencil 1300 is removed leaving the adhesive 1400 as an adhesive layer in an uncured adhesive layer 1500 on the interconnect area 1202.

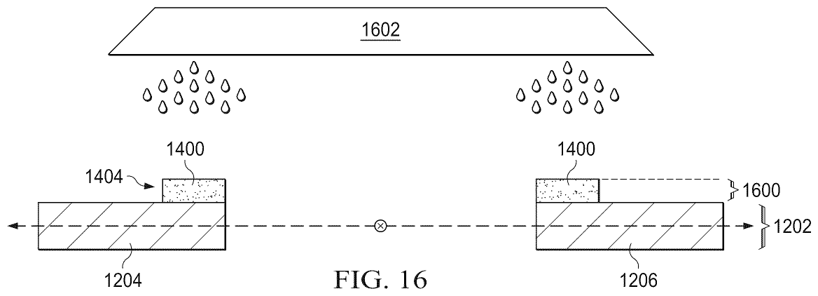

FIG. 16 illustrates an example of an eleventh stage of the method for forming the semiconductor ready for packaging with an adhesive layer. In the eleventh stage the, the uncured adhesive layer 1500 undergoes a first cure resulting in a partially cured adhesive layer 1600 as the adhesive layer. In response to the first cure, the partially cured adhesive layer 1600 is sticky or tacky. During the first cure, a first curing apparatus 1602 applies energy to the uncured adhesive layer 1500 to form the partially cured adhesive layer 1600. In one example, the first curing apparatus 1602 is a heater and the uncured adhesive layer 1500 is heated to approximately 50° C. to 180° C. In another example, the first curing apparatus 1602 is an ultraviolet (UV) source that irradiates the uncured adhesive layer 1500. The first curing apparatus irradiates the partially cured adhesive layer 1600 in a flash UV cure using a center wavelength of 365nanometers, an illumination of 60 to 80 milliWatts per centimeter squared, a light amount of 200 millijoules per square centimeter, and a time of 0.5 to 2 seconds.

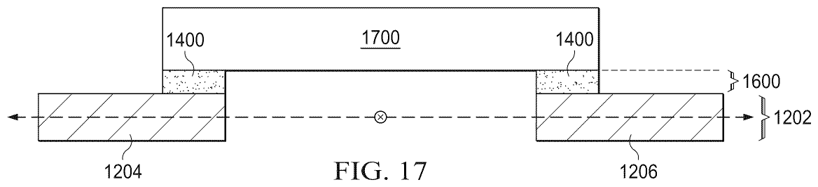

FIG. 17 illustrates an example of a twelfth stage of the method for forming the semiconductor ready for packaging with an adhesive layer. The twelfth stage include mounting a die 1700 (e.g., the die 112 of FIG. 1, the die 526 of FIG. 5, a first die 1104, a second die 1106, a third die 1108, a fourth die 1110 of FIG. 11) to the partially cured adhesive layer 1600 on the wire bond pads 1204, 1206. The die 1700 is mounted over the edges of at least two of the wire bond pads 1204, 1206. Accordingly, the die 1700 is attached to the interconnect 1200 at two wire bond pads 1204, 1206.

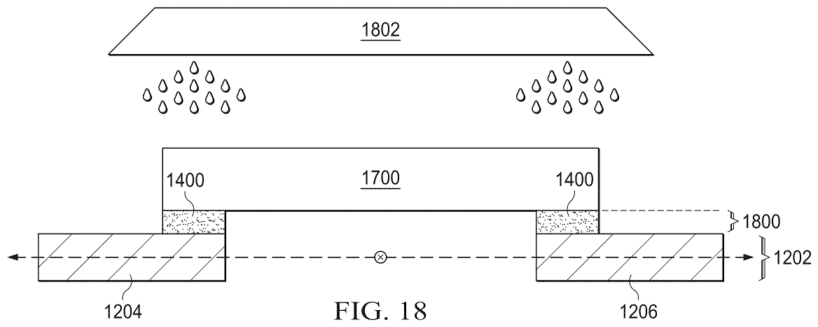

FIG. 18 illustrates an example of a thirteenth stage of the method for forming the semiconductor ready for packaging with an adhesive layer. In the thirteenth stage, the partially cured adhesive layer 1600 undergoes a second cure resulting in an adhesive layer 1800 (e.g., the adhesive layer 110 of FIG. 1, the adhesive layer 510 of FIG. 5) as the fully cured adhesive layer. The second cure is performed in response to the die 1700 being affixed to at least one wire bond pad of the plurality of wire bond pads 1204, 1206.

During the second cure, a second curing apparatus 1802 applies energy to the partially cured adhesive layer 1600 to form the adhesive layer 1800. The second curing apparatus 1802 is the same or different than the first curing apparatus 1602. In one example, the second curing apparatus 1802 is a heater and the partially cured adhesive layer 1600 is heated to approximately 150° C. to 190° C. The second cure is performed at a higher temperature than the first cure. In another example, the second curing apparatus 1802 is an ultraviolet (UV) source that irradiates the partially cured adhesive layer 1600. In some examples, the second cure is performed for a longer amount of time. In response to the second cure, the adhesive layer 1800 is hardened and rigid. The adhesive layer 1800 is not electrically conductive. Therefore, the adhesive layer 1800 provides support for the die 1700 and also electrically isolates the die 1700 from the wire bond pads 1204, 1206. Accordingly, the adhesive layer 1800 is subjected to a first cure and a second cure.

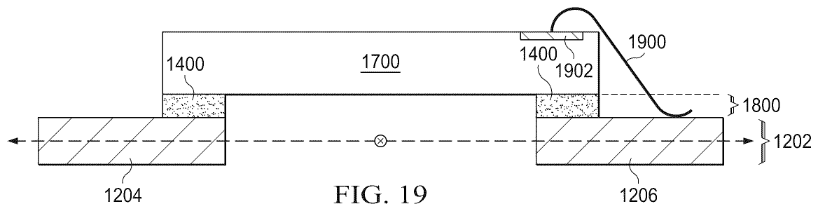

FIG. 19 shows a bond wire 1900 being attached at the die 1700 and the wire bond pads 1204, 1206 resulting in a semiconductor device (e.g., the semiconductor device 100 of FIG. 1) in a fourteenth stage. For example, the bond wire 1900 forms an electrical connection between the die 1700, at a first landing pad 1902, and the second wire bond pad 1206.

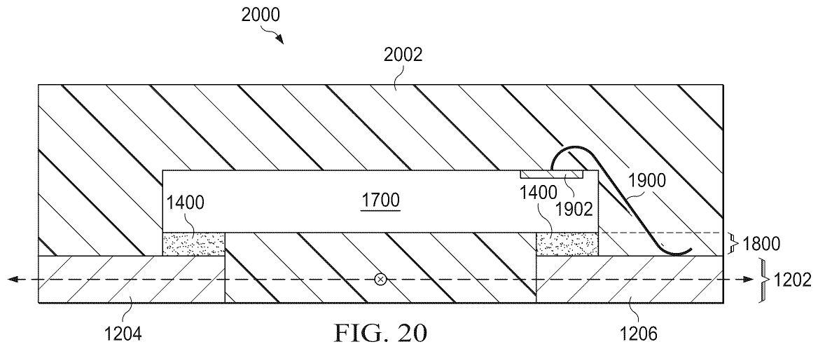

FIG. 20 shows the semiconductor device 2000 encapsulated in a molding compound 2002 (e.g., the molding compound 116 of FIG. 1, the molding compound 534 of FIG. 5) in a fifteenth stage to form a semiconductor device (e.g., the semiconductor device 100 of FIG. 1, the semiconductor device 500 of FIG. 5). The molding compound 2002 is formed of one or more insulating material, such as organic resins (e.g., epoxy), inorganic resins, and/or other suitable materials. The molding compound 2002 at least partially encapsulates the die 1700, the adhesive layer 1800, the wire bond pads 1204, 1206, and the bond wire 1900.

The adhesive layer 1800 being formed on the interconnect reduces the potential of mishandling the wafer, thereby reducing cracking and/or breakage of the wafer and simplifying the manufacturing process. Applying the adhesive 1400 to the interconnect 1200 through openings 1304, 1306 in a stencil 1300, further reduces cost and complexity of fabrication as it allows the volume and placement of the adhesive layer 1800 to be controlled. Thus, the devices and methods described herein can be used for different configurations of semiconductor devices.

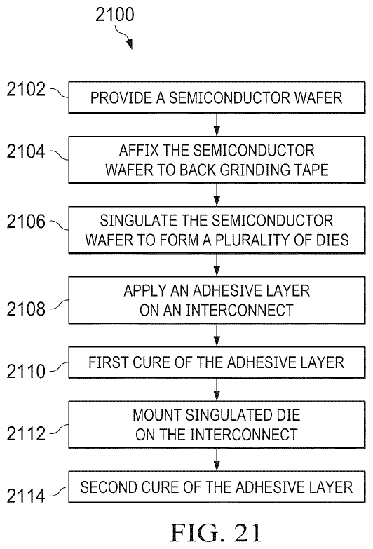

FIG. 21 illustrates an illustrates a flowchart of an example method 2100 for fabricating a wafer semiconductor with an adhesive layer.

At block 2102, the method 2100 includes providing a semiconductor wafer (e.g., the semiconductor wafer 600 of FIG. 6)

At block 2104, the method 2100 includes affixing the semiconductor wafer to back grinding tape (e.g., the back grinding tape 900 of FIG. 9). The back grinding tape supports the semiconductor wafer during formation of an array of dies.

At block 2106, the method 2100 includes singulating the semiconductor wafer to form a plurality of individual dies (e.g., a first die 1104, a second die 1106, a third die 1108, and a fourth die 1110 of FIG. 11). from the array of dies.

At block 2102, the method 2100 includes applying a stencil (e.g., the stencil 300 of FIG. 3, the stencil 400 of FIG. 4, the stencil 1300 of FIG. 13) to an interconnect (e.g. the interconnect 102 of FIG. 1, the interconnect 200 of FIG. 2, the interconnect 1200 of FIG. 12). The stencil includes a number of openings (e.g., the openings 302-312 of FIG. 3, the respective opening 402 of FIG. 4, the openings 1304, 1306 of FIG. 13) corresponding to interconnect locations (e.g., the interconnect locations 202-212 of FIG. 2, the wire bond pads 504, 506 of FIG. 5, wire bond pads 1204, 1206 of FIG. 12).

At block 2108, the method 2100 includes applying an adhesive (e.g., the adhesive 1400 of FIG. 14) to the interconnect through the number of openings to form an adhesive layer (e.g., the adhesive layer 110 of FIG. 1, the adhesive layer 510 of FIG. 5, the adhesive layer 1800 of FIG. 18) at an interconnect location of the interconnect locations.

At block 2110, the method 2100 includes performing a first cure of the adhesive layer. During the first cure, a first curing apparatus (e.g., the first curing apparatus 1602 of FIG. 16) applies energy to the adhesive layer being an uncured adhesive layer (e.g., the uncured adhesive layer 1500 of FIG. 15) so that the adhesive layer is a partially cured adhesive layer (e.g., the partially cured adhesive layer 1600 of FIG. 16).

At block 2112, the method 2100 includes attaching a die (e.g., the die 112 of FIG. 1, the die 526 of FIG. 5, a first die 1104, a second die 1106, a third die 1108, a fourth die 1110 of FIG. 11, the die 1700 of FIG. 17) to the interconnect at the at least one interconnect location. The adhesive layer electrically insulates the die from the interconnect.

At block 2114, the method 2100 includes performing a second cure of the adhesive layer. During the second cure, a second curing apparatus (e.g., the second curing apparatus 1802 of FIG. 18) applies energy to the partially cured adhesive layer to form the fully cured adhesive layer (e.g., the adhesive layer 110 of FIG. 1, the adhesive layer 510 of FIG. 5, the adhesive layer 1800 of FIG. 18). The second curing apparatus may be the same or different than the first curing apparatus. In response to the second cure, the adhesive layer is hardened and rigid. The adhesive layer is not electrically conductive. Therefore, the adhesive layer provides support for the die and also electrically isolates the die from the wire bond pads.

To form a semiconductor device, the wire bonding (i.e., wire connecting IC bond pads to wire bond pads) and potting (encapsulation of the IC chip, wire bonds, and interconnects 1200) with molding compound (e.g., the molding compound 116 of FIG. 1, the molding compound 534 of FIG. 5, the molding compound 2002 of FIG. 20). The individual packaged IC chips, including a die on an interconnect area (e.g., the interconnect area 1202 of FIG. 12) is formed by severing the saw streets (e.g., the saw streets 1208 of FIG. 12) and the tie bars (e.g., the tie bars 1210 of FIG. 12). Accordingly, a semiconductor device in which the adhesive layer is deposited on the interconnect is described. The adhesive layer undergoes a first cure, the semiconductor die is affixed to a portion of the interconnect via the adhesive layer, and a second cure is performed. Forming the adhesive layer on the interconnect reduces the potential of mishandling the wafer, thereby reducing cracking and/or breakage of the wafer and simplifying the manufacturing process.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A method of forming an integrated circuit (IC) comprising:
applying a stencil to an interconnect, wherein the stencil includes a number of openings corresponding to interconnect locations;
applying an adhesive to the interconnect through the number of openings to form an adhesive layer at an interconnect location of the interconnect locations;
performing a first cure of the adhesive layer;
attaching a die to the interconnect at the interconnect location, wherein the adhesive layer electrically insulates the die from the interconnect; and
performing a second cure of the adhesive layer.

2. The method of claim 1, wherein an opening of the number of openings has a first adhesive dimension extending in a first direction and a second adhesive dimension extending in a second direction orthogonal to the first direction, and wherein the first adhesive dimension and the second adhesive dimension are based on a first interconnect dimension and a second interconnect dimension of an interconnect location the interconnect locations.

3. The method of claim 2, wherein the interconnect locations are wire bond pads, the first interconnect dimension is a first wire bond pad dimension, and the second interconnect dimension is a second wire bond pad dimension, and wherein the die is attached to the interconnect at two wire bond pads.

4. The method of claim 2, wherein the first adhesive dimension and the second adhesive dimension are further based on a tolerance threshold.

5. The method of claim 1, wherein the stencil has a stencil thickness corresponding to an adhesive thickness of the adhesive layer.

6. The method of claim 1, further comprising:
grinding a wafer supported by grinding tape; and
sawing the wafer to form the die in a plurality of dies, supported by the grinding tape.

7. The method of claim 1, wherein the adhesive is a B-stage epoxy resin.

8. A method of forming an integrated circuit (IC) comprising:
applying an adhesive to an interconnect to form an adhesive layer at a die attach pad;
performing a first cure of the adhesive layer;
attaching a die to the interconnect at a die attach pad, wherein the adhesive layer electrically insulates the die from the interconnect; and
performing a second cure of the adhesive layer.

9. The method of claim 8, further comprising:
applying a stencil to the interconnect, wherein the stencil includes a number of openings corresponding to a die attach pad on the interconnect.

10. The method of claim 9, wherein an opening of the number of openings has a first adhesive dimension extending in a first direction and a second adhesive dimension extending in a second direction orthogonal to the first direction, and wherein the first adhesive dimension and the second adhesive dimension are based on a first die dimension and a second die dimension of the die.

11. The method of claim 10, wherein the first adhesive dimension and the second adhesive dimension are further based on a tolerance threshold.

12. The method of claim 9, wherein the stencil has a stencil thickness corresponding to an adhesive thickness of the adhesive layer.

13. The method of claim 8, the method further comprising:
grinding a wafer supported by grinding tape; and
sawing the wafer to form a plurality of dies, including the die, supported by the grinding tape.

14. The method of claim 8, wherein the adhesive is applied by a screen-printing process.

15. The method of claim 8, wherein the adhesive is a B-stage epoxy resin.

16. A semiconductor device comprising:
a plurality of wire bond pads having an adhesive layer applied to a region of surfaces of the plurality of wire bond pads, wherein the adhesive layer has a first adhesive dimension extending in a first direction and a second adhesive dimension extending in a second direction orthogonal to the first direction; and
a die having a base surface affixed to the plurality of wire bond pads by the adhesive layer, wherein the base surface has a first die dimension and a second die dimension orthogonal to the first die dimension, and wherein the first adhesive dimension and the second adhesive dimension are based on a first wire bond pad dimension and a second wire bond pad dimension of a wire bond pad of the wire bond pads.

17. The semiconductor device of claim 16, wherein the adhesive layer is formed of B-stage adhesive that is subjected to a first cure and a second cure.

18. The semiconductor device of claim 17, wherein the first cure is performed in response to the adhesive layer being applied to the region of the surfaces of the plurality of wire bond pads and the second cure is performed in response to the die being affixed to at least one wire bond pad of the plurality of wire bond pads.

19. The semiconductor device of claim 16, wherein the adhesive layer includes a first adhesive section and a second adhesive section that coplanar and separated by a gap distance.

20. The semiconductor device of claim 16 further comprising:
a bond wire attached at the die and a wire bond pad of the plurality of wire bond pads; and
a molding compound that encapsulates the bond wire, the wire bond pad, and the die.
